(19) United States
(12) Patent Application Publication
(10) Pub. No.: US 2025/0031441 A1
(43) Pub. Date: Jan. 23, 2025

(54) SEMICONDUCTOR DEVICE AND METHOD OF FORMING THE SAME

(71) Applicant: Taiwan Semiconductor Manufacturing Company, Ltd., Hsinchu (TW)

(72) Inventors: Feng-Ming CHANG, Hsinchu County (TW); Che-Chia Hsu, Taoyuan city (TW); Kao-Ting Lai, Hsinchu (TW); Jhon Jhy Liaw, Hsinchu County (TW)

(73) Assignee: Taiwan Semiconductor Manufacturing Company, Ltd., Hsinchu (TW)

(21) Appl. No.: 18/354,603

(22) Filed: Jul. 18, 2023

(51) Int. Cl. H01L 27/092; H01L 21/8238

(52) U.S. Cl. CPC H01L 27/092; H01L 21/823807

(57) ABSTRACT

A semiconductor device includes a plurality of first nanosheets of a first conductive type, a plurality of second nanosheets of a second conductive type and a gate structure. The gate structure wraps the first nanosheets and the second nanosheets, wherein a first thickness of at least one of the first nanosheets is smaller than a second thickness of at least one of the second nanosheets.

### BACKGROUND

The semiconductor integrated circuit (IC) industry has experienced exponential growth. Technological advances in IC materials and design have produced generations of ICs where each generation has smaller and more complex circuits than the previous generation. In the course of IC evolution, functional density (e.g., the number of interconnected devices per chip area) has generally increased while geometry size (e.g., the smallest component (or line) that can be created using a fabrication process) has decreased. This scaling down process generally provides benefits by increasing production efficiency and lowering associated costs. However, scaling down has also led to challenges that may not have been presented by previous generations at larger geometries.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1-14, 15A, 15B, 16-21, 22A and 22B illustrate varying views of a method of forming a semiconductor device in accordance with some embodiments.

FIG. 23A and FIG. 23B schematically illustrate local cross-sectional views of various semiconductor devices in accordance with some embodiments.

FIGS. 24 to 27, 28A and 28B illustrate cross-sectional views of stages of forming a semiconductor device.

FIG. 29 illustrates a flow chart of a method of forming a semiconductor structure in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Embodiments of the present disclosure may be used to form gate stacks suitable for use in planar bulk metal-oxide-semiconductor field-effect transistors (MOSFETs), multi-gate transistors (planar or vertical) such as FinFET devices, gate-all-around (GAA) devices, Omega-gate (a-gate) devices, or Pi-gate (H-gate) devices, as well as strained-semiconductor devices, silicon-on-insulator (SOI) devices, partially-depleted SOI devices, fully-depleted SOI devices, or other devices as known in the art. In addition, embodiments disclosed herein may be employed in the formation of p-type and/or n-type devices. One of ordinary skill may recognize other embodiments of semiconductor devices that may benefit from aspects of the present disclosure.

The gate all around (GAA) transistor structures may be patterned by any suitable method. For example, the structures may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the GAA structure.

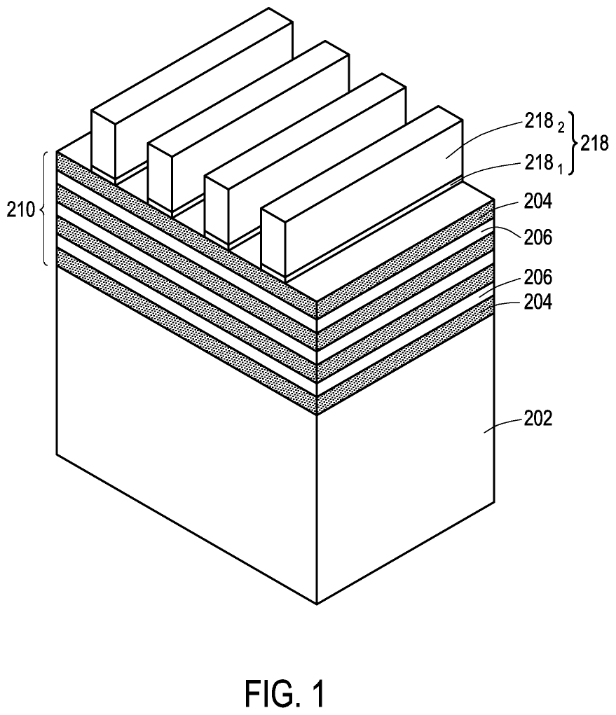

FIG. 1 to FIG. 22B illustrate varying views of a method of forming a semiconductor device in accordance with some embodiments. The semiconductor device illustrated in the following embodiments may be, for example but not limited to, a multi-gate device. As used herein, the term “multi-gate device” is used to describe a device (e.g., a semiconductor transistor) that has at least some gate material disposed on multiple sides of at least one channel of the device. In some examples, the multi-gate device may be referred to as a gate-all-around (GAA) device having a gate material disposed on four sides of at least one channel member of the device. The channel member may be referred to as “nanosheet” or “nanowire” which is used herein to designate any material portion with nanoscale, or even microscale dimensions, and having an elongate shape, regardless of the cross-sectional shape of this portion. Thus, this term designates both circular and substantially circular cross-section elongate material portions, and beam or bar-shaped material portions including, for example but not limited to, a cylindrical in shape or substantially rectangular cross-section. The method is merely an example, and is not intended to limit the present disclosure beyond what is explicitly recited in the claims. Additional steps may be provided before, during, and after method, and some of the steps described can be moved, replaced, or eliminated for additional embodiments of method. Additional features may be added in the semiconductor device depicted in FIG. 1 to FIG. 18C and some of the features described below can be replaced, modified, or eliminated in other embodiments of the semiconductor device.

FIG. 1 to FIG. 5 illustrate perspective views of stages of forming a semiconductor device. Referring to FIG. 1, a substrate 202 is provided. In some embodiments, the substrate 202 includes an element semiconductor such as silicon or germanium, a compound semiconductor such as silicon carbide, gallium arsenic, gallium phosphide, indium phosphide, indium arsenide and indium antimonide, an alloy semiconductor such as SiGe, GaAsP, AlInAs, AlGaAs, GaInAs, GaInP and GaInAsP or a combination thereof. The substrate 202 may include various doped regions (e.g., p-type well and/or n-type well) depending on design requirements. In some embodiments, the doped regions may be doped with p-type or n-type dopants. The doped regions may be configured for an n-type device, or alternatively, configured for a p-type device. In some embodiments, an anti-punch-through (APT) implantation is performed on a top portion of the substrate 202 to form an APT region. The conductivity type of the dopants implanted in the APT region is the same as that of the doped regions (or wells). The APT region may extend under the subsequently formed strained layers, and are used to reduce the leakage from the strained layers to the substrate 202. The strained layers are referred to “source/drain regions” in some examples. Source/drain region(s) may refer to a source or a drain, individually or collectively dependent upon the context. For clarity, the doped regions and the APT region are not illustrated in FIG. 1 and subsequent drawings.

In some embodiments, a semiconductor stack 210 is formed over the substrate 202. The semiconductor stack 210 includes first blanket layers 204 and second blanket layers 206 stacked alternately. The first and second blanket layers are referred to as “first and second layers”, “first and second materials”, “first and second compositions” or “first and second semiconductor materials” in some examples. The first blanket layers 204 and second blanket layers 206 include different materials. In some embodiments, the first blanket layers 204 are SiGe layers having a germanium percentage in the range between about 15 wt % and 40 wt %, and the second blanket layers 206 are Si layers free of germanium. In other embodiments, either of the first blanket layers 204 and second blanket layers 206 may include other materials such as germanium, a compound semiconductor (e.g., silicon carbide, gallium arsenide, gallium phosphide, indium phosphide, indium arsenide, or indium antimonide), an alloy semiconductor (e.g., SiGe, GaAsP, AlInAs, AlGaAs, InGaAs, GaInP, or GaInAsP), the like, or a combination thereof.

The first blanket layers 204 and the second blanket layers 206 have materials with different etching selectivities. In some embodiments, the first blanket layers 204 and the second blanket layers 206 are formed by an epitaxial growth process, such as a molecular beam epitaxy (MBE) process, a metalorganic chemical vapor deposition (MOCVD) process, or the like. In the case, the first blanket layers 204 are epitaxial SiGe layers, and the second blanket layers 206 are epitaxial Si layers. In some embodiments, the first and second blanket layers 204 and 206 are substantially dopant-free (i.e., having an extrinsic dopant concentration from about 0 cm⁻³ to about 1×10¹⁷ cm⁻³), where for example, no intentional doping is performed during the epitaxial growth process. In other embodiments, the first blanket layers 204 and the second blanket layers 206 are formed by a suitable deposition, such as chemical vapor deposition (CVD), atomic layer deposition (ALD), or the like. In the case, the first blanket layers 204 are poly-SiGe layers, and the second blanket layers 206 are poly-Si layers.

In the illustrated embodiment, the bottom layer and the top layer of the semiconductor stack 210 are SiGe layers. However, the disclosure is not limited thereto. In other embodiments (not shown), the bottom layer of the semiconductor stack 210 is a Si layer and the top layer of the semiconductor stack 210 is a SiGe layer. It is noted that seven layers of first blanket layers 204 and six layers of second blanket layers 206 are illustrated in FIG. 1, which is for illustrative purposes only and not intended to be limiting beyond what is specifically shown in the drawings. Specifically, any number of epitaxial layers may be formed in the semiconductor stack 210; the number of layers depending on the desired number of channel regions for the device 200.

In some embodiments, each of the first blanket layers 204 and the second blanket layers 206 has a thickness ranging from about 5 nm to about 15 nm. As described in more detail below, the second blanket layer 206 may serve as channel region(s) for a subsequently formed multi-gate device and its thickness chosen based on device performance considerations. The first blanket layer 204 may be configured to define a gap between adjacent channel region(s) for a subsequently formed multi-gate device and its thickness chosen based on device performance considerations.

Still referring to FIG. 1, mask strips 218 are formed over the semiconductor stack 210. In some embodiments, a mask layer is formed on the semiconductor stack 210. The mask layer may include a dielectric material, such as silicon oxide, silicon nitride, SiON, SiC, SiCN, SiCON, the like, or a combination thereof. Other materials such as a low-k material may be applicable. The low-k material has a dielectric constant less than 3.9, less than 3, less than 2.5, or even less. In some embodiments, the mask layer includes a first mask layer and a second mask layer over the second mask layer. For example, the first mask layer is a pad oxide layer made of a silicon oxide, which may be formed by a thermal oxidation. The second mask layer is made of a silicon nitride (SiN), which is formed by chemical vapor deposition (CVD), low pressure CVD (LPCVD), plasma enhanced CVD (PECVD), physical vapor deposition (PVD), atomic layer deposition (ALD), or a suitable process. The mask layer is then patterned into the mask strips 218 by using photolithography and etching processes. In some embodiments, each of the mask strips 218 includes a first mask pattern 2181 and a second mask pattern 2182 over the first mask pattern 2181.

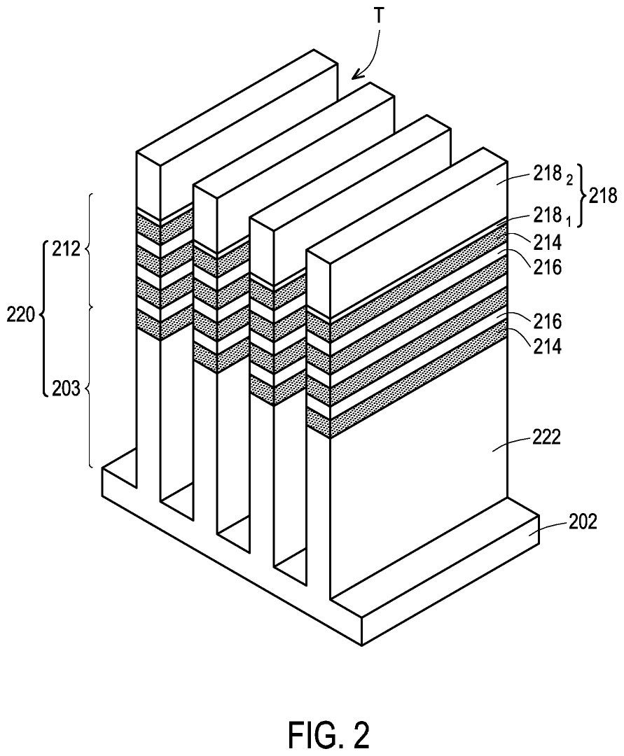

Referring to FIG. 2, the semiconductor stack 210 and the substrate 202 are patterned by using the mask strips 218 as a mask, so as to form semiconductor strips 220 separated by trenches T. The patterning process includes an etching process, such as a dry etching or the like. As shown in FIG. 2, the trenches T extend into the substrate 202, and have lengthwise directions parallel to each other. Herein, the semiconductor strips 212 are referred to as “hybrid fins” in some examples. In some embodiments, each of the semiconductor strips 220 includes a fin 203 protruding from the substrate 202, and a nanosheet stack 212 on the fin 203. In some embodiments, the nanosheet stack 212 includes nanosheets 214 and nanosheets 216 stacked alternately. The nanosheets are referred to as “nanowires” or “semiconductor nanosheets” in some examples. In some embodiments, the first nanosheets are referred to as “sacrificial portions”, “dummy portions” or “dummy regions” which will be subsequently removed and replaced by a metal gate structure, and the second nanosheets are referred to as “channel members”, “channel portions” or “channel regions” which will serve as semiconductor channels. Although only four semiconductor strips 220 are illustrated in FIG. 2, the embodiments of the present disclosure are not limited thereto. In other embodiments, the number of the semiconductor strips 220 may be adjusted as needed. The adjacent semiconductor strips 220 may have the same width or different widths.

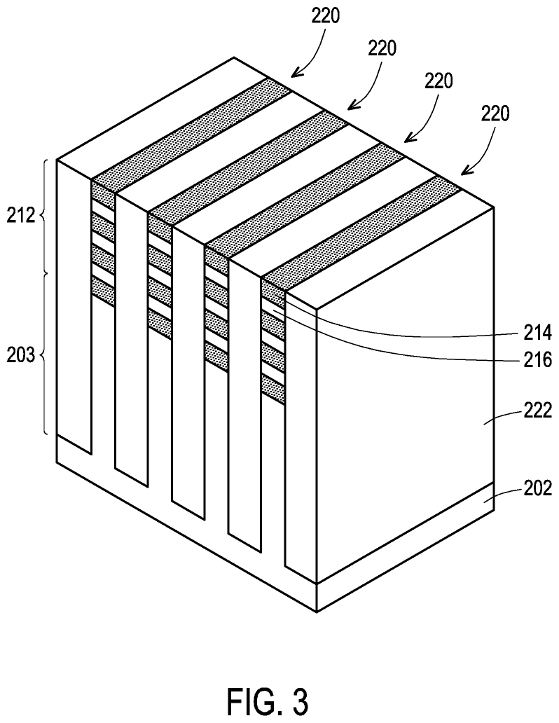

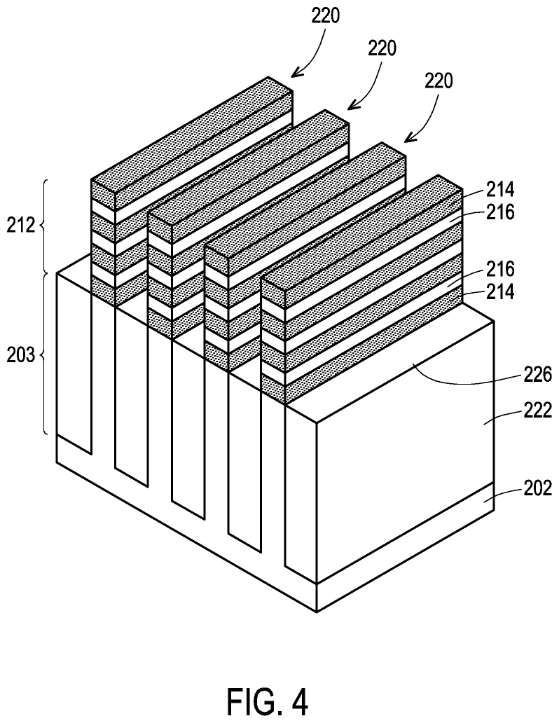

Referring to FIG. 3 and FIG. 4, insulating regions 222 are formed in the trenches T between the semiconductor strips 220. In some embodiments, an insulating material is formed on the substrate 202, covering the semiconductor strips 220 and filling up the trenches T. In addition to the semiconductor strips 220, the insulating material further covers the mask strips 218. The insulating material may include silicon oxide, silicon nitride, silicon oxynitride, a spin-on dielectric material, or a low-k material. The low-k material has a dielectric constant less than 3.9, less than 3, less than 2.5, or even less. The insulating material may be formed by flowable chemical vapor deposition (FCVD), high-density-plasma chemical vapor deposition (HDP-CVD), sub-atmospheric CVD (SACVD), or spin-on process. A planarization process may be performed to remove a portion of the insulating material and the mask strips 218, until the semiconductor strips 220 are exposed. In the case, as shown in FIG. 3, the top surfaces of the semiconductor strips 220 are substantially coplanar with the top surfaces of the insulating regions 222. In some embodiments, the planarization process includes a chemical mechanical polish (CMP), an etching back process, the like, or a combination thereof.

Referring to FIG. 3 and FIG. 4, the insulating regions 222 are recessed, until the semiconductor strips 220 protrude from top surfaces of the remaining insulating regions 222. Specifically, after the recessing operation, the top surfaces of the insulating regions 222 are lower than the top surfaces of the semiconductor strips 220 and the nanosheet stacks 212 are exposed by the insulating regions 222. The top surfaces of the insulating regions 222 may be substantially coplanar with or lower than bottom surfaces of the nanosheet stacks 212. Further, the top surfaces of the insulating regions 222 may have a flat surface, a convex surface, a concave surface (such as dishing), or a combination thereof. In some embodiments, the insulating regions 222 are recessed by using an appropriate etching process, such as a wet etching process with hydrofluoric acid (HF), a dry etching process, or a combination thereof. In some embodiments, a height difference between the top surfaces of the semiconductor strips 220 and the top surfaces of the insulating regions 222 ranges from about 30 nm to about 100 nm. The insulating regions 222 are referred to as “isolation strips”, “shallow trench isolation (STI) regions” or “deep trench isolation (DTI) regions” in some examples.

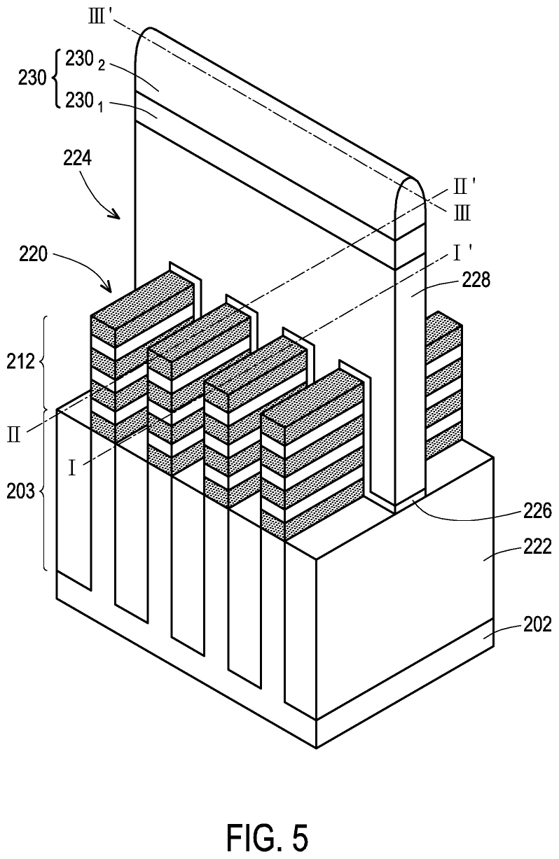

Referring to FIG. 5, at least one dummy gate stack 224 is formed across portions of the nanosheet stacks 212 and portions of the insulating regions 222. The dummy gate stack 224 may extend along a direction different from (e.g., perpendicular to) the extending direction of the nanosheet stacks 212. The dummy gate stack 224 defines the channel regions of the GAA device. The dummy gate stack 224 includes a dummy gate dielectric layer 226 and a dummy gate electrode layer 228 over the dummy gate dielectric layer 226. In some embodiments, a dummy gate dielectric material and a dummy gate electrode material are blanket-formed over the semiconductor strips 220. The dummy gate dielectric material and the dummy gate electrode material are deposited using CVD, LPCVD, PECVD, PVD, ALD, or a suitable process. A mask layer 230 is formed over the dummy gate electrode material. The mask layer 230 may include a dielectric material, such as silicon oxide, silicon nitride, SiON, SiC, SiCN, SiCON, the like, or a combination thereof. Other materials such as a low-k material may be applicable. The low-k material has a dielectric constant less than 3.9, less than 3, less than 2.5, or even less. In some embodiments, the mask layer 230 includes a first mask layer 2301 (e.g., silicon oxide layer) and a second mask layer 2302 (e.g., silicon nitride layer) over the first mask layer 2301. Thereafter, the dummy gate dielectric material and dummy gate electrode material are patterned into the dummy gate stack 224 by using the mask layer 230 as a mask. The mask layer 230 is regarded as part of the dummy gate stack 224 in some examples.

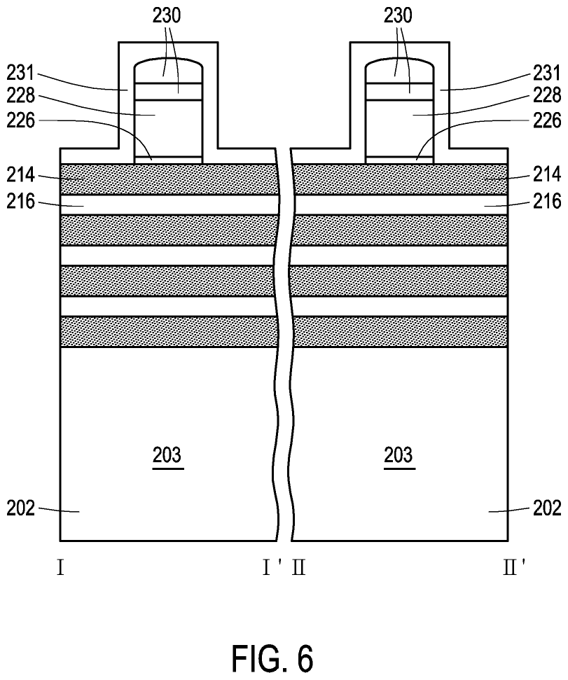

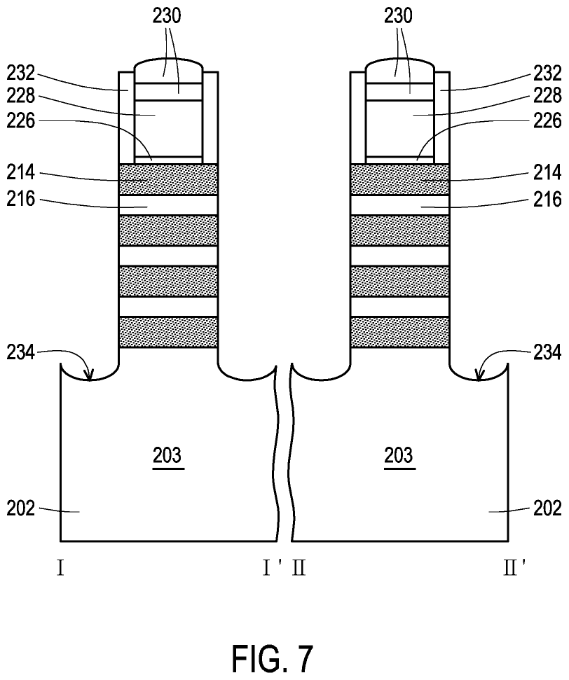

FIG. 6 to FIG. 14 illustrate cross-sectional views of stages of forming a semiconductor device, and FIG. 6 to FIG. 14 are taken along lines I-I′ and II-II′ of FIG. 5. The line I-I′ is substantially parallel to the line II-II′. Referring to FIG. 6 and FIG. 7, spacers 232 are formed on sidewalls of the dummy gate stack 224 and sidewalls of the nanosheet stacks 212 by depositing a spacer material 231 and followed by an anisotropic etching. In some embodiments, the spacers 232 include a dielectric material, such as silicon oxide, silicon nitride, SiON, SiC, SiCN, SiCON, or a combination thereof. Other materials such as a low-k material may be applicable. The low-k material has a dielectric constant less than 3.9, less than 3, less than 2.5, or even less. Although the spacers 232 illustrated in FIG. 7 have a single-layer structure, the embodiments of the present disclosure are not limited thereto. In other embodiments, the spacers 232 may have a multi-layer structure. For example, the spacers 232 may include a silicon oxide layer and a silicon nitride layer on the silicon oxide layer.

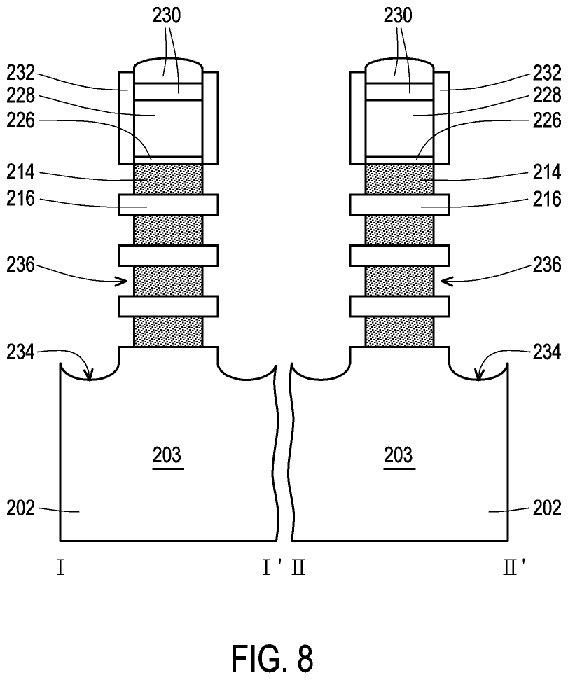

Upon the spacer forming operation, the dummy gate stack 224 and the spacers 232 cover middle portions of the nanosheet stacks 212, and reveal the opposite end portions of the nanosheet stacks 212. As shown in FIG. 8, the end portions of the nanosheet stacks 212 are removed and the underlying fins 203 are recessed to form recesses 234. In other words, the end portions of the nanosheet stacks 212 are entirely removed and portions of the fins 203 are further removed. The recesses 234 are referred to as “source/drain (S/D) recesses” in some examples. In some embodiments, the end portions of the nanosheet stacks 212 may be removed by an anisotropic etching process, an isotropic etching process, or a combination thereof. In some embodiments, the top surfaces of the recesses 234 are lower than the top surfaces of the insulating regions 222. In some embodiments, the spacers 232 on the nanosheet stacks 212 are partially removed during the recess forming operation, and the remaining spacers 233 are left standing over and aligned to the edges of insulating regions 222, with the recesses 234 formed therebetween, as shown in FIG. 7. In many embodiments, the method of forming the recesses 234 includes performing a suitable etching process, such as a dry etching process, a wet etching process, or an RIE process.

Referring to FIG. 8, portions of the nanosheets 214 are laterally recessed. In some embodiments, the portions of the nanosheets 214 exposed by the recesses 234 are removed, and thus, cavities 236 are respectively formed between the nanosheets 216. In some embodiments, the nanosheets 214 are laterally recessed by a wet etching, a dry etching, or a combination thereof. For example, the nanosheets 214 may be selectively etched by using a wet etchant including, for example but not limited to, ammonium hydroxide (NH₄OH), tetramethylammonium hydroxide (TMAH), ethylenediamine pyrocatechol (EDP), or potassium hydroxide (KOH) solutions. In other embodiments, before laterally recessing the portions of the nanosheets 214, the end portions of the nanosheets 214 exposed by the recesses 234 may be selectively oxidized, so as to increase the etching selectivity between the first and second nanosheets 214 and 216. In other embodiments, the oxidation process may be performed by exposing to a wet oxidation process, a dry oxidation process, or a combination thereof. The chemical used in the oxidation process may include H₂SO₄ or the like.

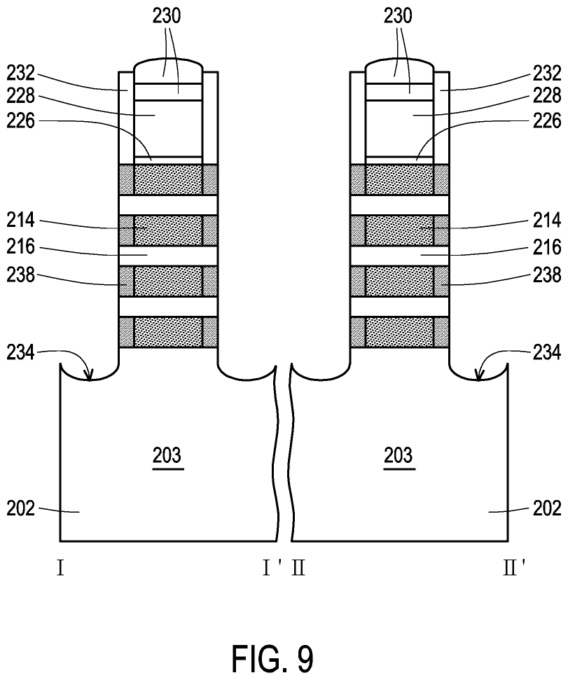

Referring to FIG. 8 and FIG. 9, inner spacers 238 are formed in the cavities 236. In some embodiments, an inner spacer material is formed on the substrate 202. In some embodiments, the inner spacer material conformally covers the recesses 234 and the spacers 232 on the dummy gate stack 224, and further fills in the cavities 236 to reduce the size of the cavities 236 or completely fill in the cavities 236. In some embodiments, the inner spacer material includes silicon oxide, silicon nitride, silicon carbide, silicon carbide nitride, silicon oxide carbide, silicon carbide oxynitride, and/or other suitable dielectric materials, and may be formed by ALD or a suitable method. In other embodiments, the inner spacer material includes a low-k material having a dielectric constant less than 3.9, less than 3, less than 2.5, or even less. Thereafter, the inner spacer material is partially removed to form inner spacers 238 in the cavities 236. In some embodiments, the inner spacer material layer is partially removed by a plasma dry etching or a suitable method. Generally, the plasma dry etching etches a layer in wide and flat areas faster than a layer in concave (e.g., holes, grooves and/or slits) portions. Thus, the remaining inner spacer material forms the inner spacers 238 inside the cavities 236.

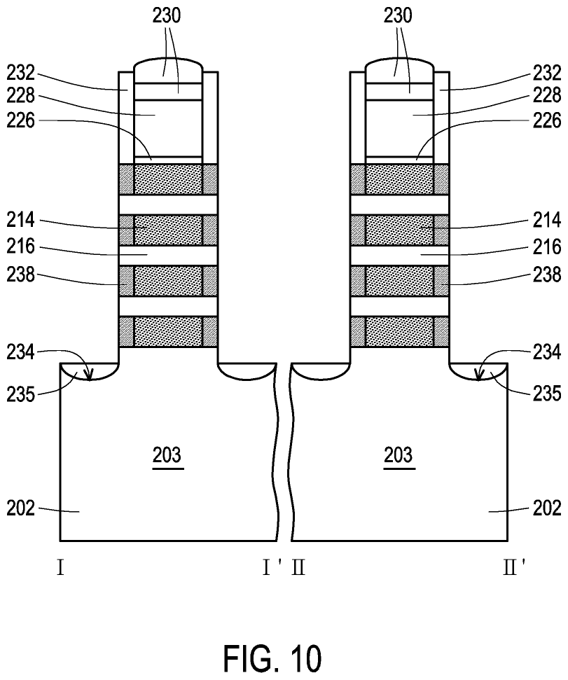

Referring to FIG. 10, a liner layer 235 is formed in bottoms of the recesses 234. In some embodiments, the liner layer 235 includes Si, Ge, SiGe, the like, or a combination thereof. In some embodiments, the liner layer 235 is formed by an epitaxial growth process and is grown from the bottoms of the recesses 234. However, the disclosure is not limited thereto. In other embodiments, the liner layer 235 is formed by ALD and is formed in the bottoms of the recesses 234 and covers the inner spacers 238 and the nanosheets 216.

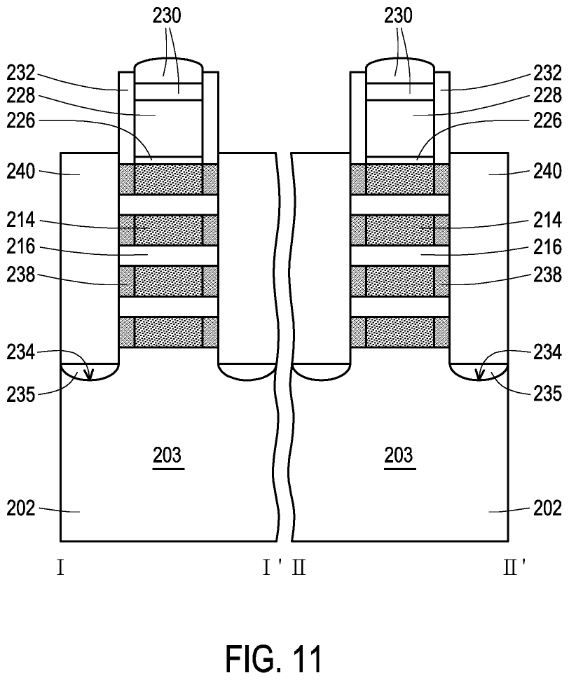

Referring to FIG. 11, strained layers 240 are epitaxially grown from the liner layer 235. In some embodiments, the strained layers 240 are used to strain or stress the second nanosheets (which may be referred to as channel members) 216 and the fins 203. Herein, the strained layers may be referred to as “epitaxial layers”, “S/D regions” or “highly doped low resistance materials” in some examples. In some embodiments, the strained layers 240 include source regions disposed at one side of the dummy gate stack 224 and drain regions disposed at another side of the dummy gate stack 224. The source regions cover ends of the fins 203, and the drain regions cover opposite ends of the fins 203. The strained layers 240 are abutted and electrically connected to the nanosheets 216, while the strained layers 240 are electrically isolated from the nanosheets 214 by the inner spacers 238. In some embodiments, the strained layers 240 extend beyond the top surfaces of the nanosheet stacks 212 (not shown). However, the embodiments of the present disclosure are not limited thereto, in other embodiments, the top surfaces of the strained layers 240 are substantially flushed with the top surfaces of the nanosheet stacks 212.

In some embodiments, the strained layers 240 are grown from the material of the liner layer 235. For example, when the liner layer 235 is polysilicon layer, the strained layers may be a silicon-containing material. In some embodiments, the liner layer 235 is beneficial for forming the strained layers 240 in the recesses 234 because the liner layer 235 improves a good interface for epitaxially growing the strained layers 240.

In some other embodiments, the strained layers 240 include a suitable material, for a p-type device. For example, if the liner layer 235 is silicon, the strained layers 240 may include SiGe, SiGeB, Ge, GeSn, or the like. In other embodiments, the strained layers 240 includes a suitable material for an n-type device. For example, if the liner layer 235 is silicon, the strained layers 240 may include silicon, SiC, SiCP, SiP, or the like. In some embodiments, the strained layers 240 are formed by MOCVD, MBE, ALD, or the like.

In some embodiments, the strained layers 240 may be doped with a conductive dopant. For example, the strained layers 240 may be epitaxial-grown with a p-type dopant for straining a p-type device. That is, the strained layers 240 is doped with the p-type dopant to be the source and the drain of the p-type device. The p-type dopant includes boron or BF₂, and the strained layers 240 may be epitaxial-grown by LPCVD process with in-situ doping. In other embodiments, the strained layers 240 is epitaxial-grown with an n-type dopant for straining an n-type device. That is, the strained layers 240 is doped with the n-type dopant to be the source and the drain of the n-type device. The n-type dopant includes arsenic and/or phosphorus, and the strained layers 240 may be epitaxial-grown by LPCVD process with in-situ doping.

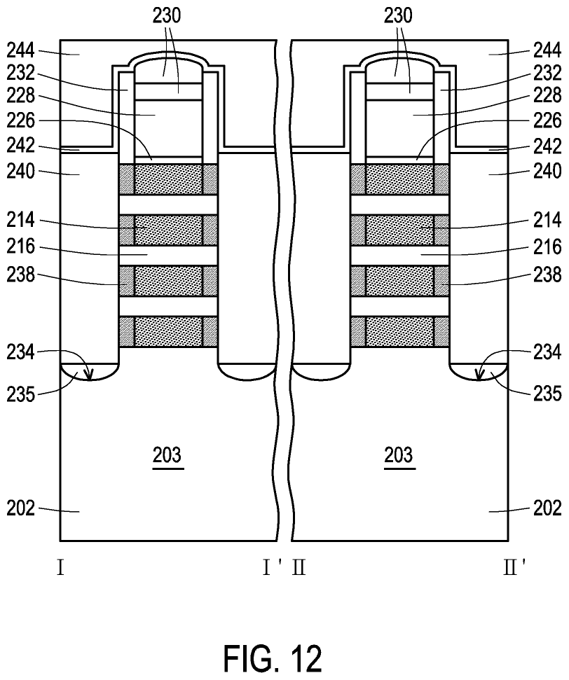

Referring to FIG. 12, a contact etch stop layer (CESL) 242 is formed over the strained layers 240. In some embodiments, the CESL 242 conformally covers the upper portions of the strained layers 240 and the sidewalls of the spacers 232 and 233. The CESL 242 may include silicon nitride, silicon oxynitride, silicon nitride with oxygen (O) or carbon (C) elements, metal oxide such as Al₂O₃, the like, or a combination thereof, and may be formed by CVD, PVD. ALD, or a suitable process.

Thereafter, an interlayer dielectric (ILD) layer 244 is formed over the CESL 242. In some embodiments, the ILD layer 244 includes silicon oxide, silicon nitride, silicon oxynitride, phosphosilicate glass (PSG), borophosphosilicate glass (BPSG), spin-on glass (SOG), fluorinated silica glass (FSG), carbon doped silicon oxide (e.g., SiCOH), polyimide, the like, or a combination thereof. In some other embodiments, the ILD layer 244 includes a low-k material. The low-k material has a dielectric constant less than 3.9, less than 3, less than 2.5, or even less. Examples of the low-k material include BLACK DIAMOND® (Applied Materials of Santa Clara, Calif.), Xerogel, Aerogel, amorphous fluorinated carbon, Parylene, BCB (bis-benzocyclobutenes), Flare, SILK® (Dow Chemical, Midland, Mich.), hydrogen silsesquioxane (HSQ) or fluorinated silicon oxide (SiOF), the like, or a combination thereof. In other embodiments, the ILD layer 244 may have a single-layer structure or a multi-layer structure. In some embodiments, the ILD layer 244 is formed by FCVD, CVD, HDPCVD, SACVD, spin-on process, sputtering, or a suitable process.

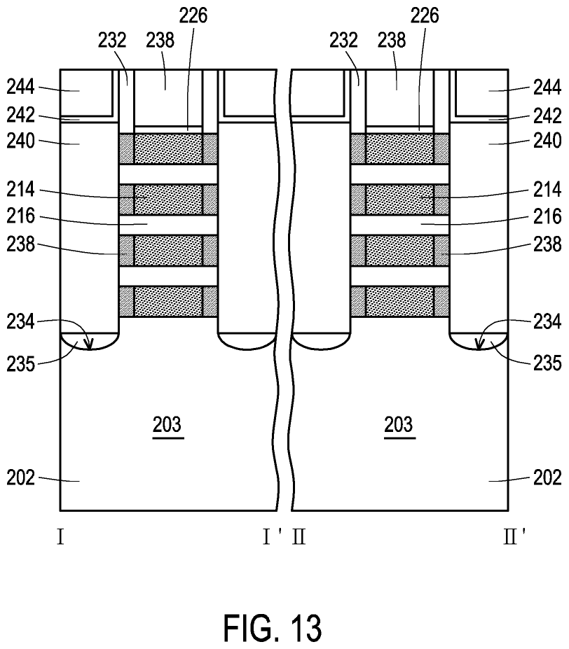

Referring to FIG. 13, a planarization process such as CMP is performed to planarize the topography of the structure. In some embodiments, the ILD layer 244, the CESL layer 242, the spacers 232 are partially removed and the mask layer 230 is entirely removed, until the top surface of the dummy gate electrode layer 228 is exposed. In some embodiments, the top surface of the dummy gate electrode layer 228 is substantially flushed with the top surfaces of the ILD layer 244, the CESL layer 242 and the spacers 232.

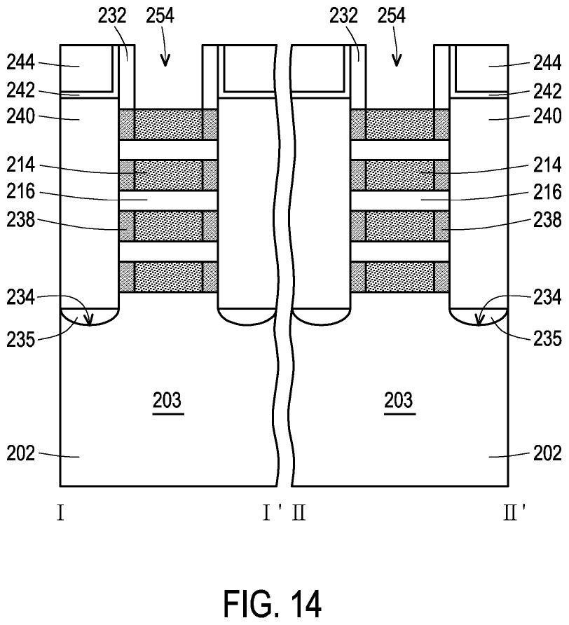

Referring to FIG. 14, the dummy gate stack 224 (including the dummy gate electrode layer 228 and the dummy gate dielectric layer 226) is removed to form a gate trench 254. The ILD layer 244 and the CESL layer 242 protect the stained layers 240 during the removal of the dummy gate stack 224. The dummy gate stack 224 may be removed using plasma dry etching and/or wet etching. When the dummy gate electrode layer 228 is polysilicon and the ILD layer 244 is silicon oxide, a wet etchant such as a TMAH solution may be used to selectively remove the dummy gate electrode layer. The dummy gate dielectric layer 226 is then removed using plasma dry etching and/or wet etching.

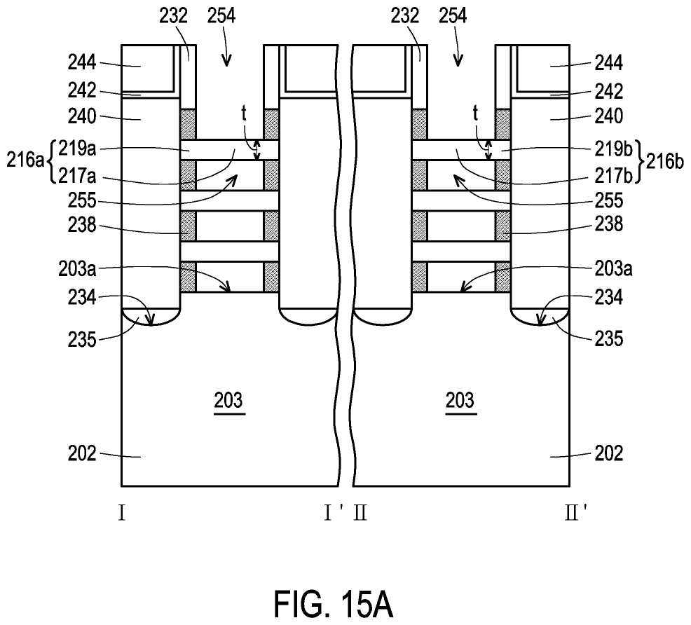

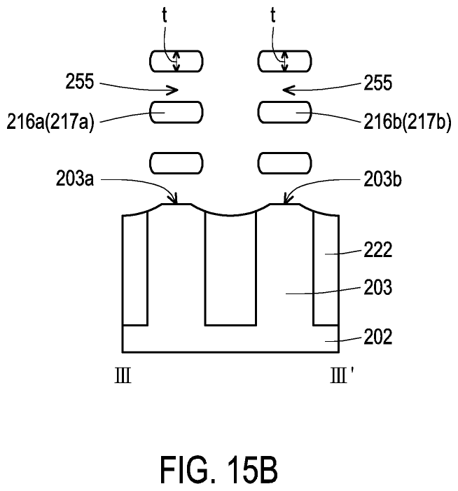

FIG. 15A and FIG. 15B illustrate cross-sectional views of a stage of forming a semiconductor device, FIG. 15A is taken along lines I-I′ and II-II′ of FIG. 5, and FIG. 15B is taken along a line III-III′ of FIG. 5. The line III-III′ is substantially perpendicular to lines I-I′ and II-II′, respectively. In some embodiments, the line III-III′ cuts the main portions 217a, 217b of the nanosheets 216a, 216b of FIG. 15A, and thus FIG. 15B shows a cross-sectional view of the main portions 217a, 217b of the nanosheets 216a, 216b.

Referring to FIGS. 15A and 15B, the nanosheets 214 are removed. In some embodiments, an etching process is performed to remove the nanosheets 214. In the case, the nanosheets 214 may be completely removed to form gaps 255 between the nanosheets 216 (216a, 216b). Accordingly, the nanosheets 216 (216a, 216b) are separated from each other by the gaps 255. In addition, the bottommost nanosheet 216 (216a, 216b) may also be separated from the fin 203 by the gaps 255. As a result, the nanosheets 216 (216a, 216b) are suspended. The opposite ends of the suspended nanosheets 216 (216a, 216b) are connected to strained layers 240.

In some embodiments, the nanosheets 216 (216a, 216b) include silicon, and the nanosheets 214 include silicon germanium. The nanosheets 214 may be selectively removed by oxidizing the nanosheets 214 using a suitable oxidizer, such as ozone. Thereafter, the oxidized nanosheets 214 may be selectively removed from the gate trench 254. In some embodiments, the etching process includes a dry etching process to selectively remove the nanosheets 214, for example, by applying an HCl gas at a temperature of about 20° C. to about 300° C., or applying a gas mixture of CF₄, SF₆, and CHF₃.

In some embodiments, as shown in FIGS. 15A and 15B, the nanosheets 216 for a first conductive type device (e.g., n-type device) are referred to as nanosheets 216a, and the nanosheets 216 for a second conductive type device (e.g., p-type device) are referred to as nanosheets 216b. The nanosheets 216a, 216b separated from each and vertically stacked are also referred to as a “stack of semiconductor nanosheets” in some examples. For example (not shown), there are three stacks of nanosheets 216b and three stacks of nanosheets 216a. It is noted that FIG. 15B illustrates a region in which the stacks of the nanosheets 216b and the stacks of the nanosheets 216a are disposed adjacent to each other. However, the disclosure is not limited thereto. In alternative embodiments, the stacks of nanosheets 216b and the stacks of nanosheets 216a are distant from each other and a separation structure is disposed therebetween. In some embodiments, the nanosheet 216a and the nanosheet 216b have substantially the same material which is the same as the second blanket layer 206. For example, the nanosheet 216a and the nanosheet 216b is Si layer free of germanium. In alternative embodiments, the dopants in the doped regions (or wells) and/or the strained layers 240 may be diffused into the nanosheets 216a, 216b due to the thermal process. In such embodiments, the nanosheet 216a may have first conductive type dopants, and the nanosheet 216b may have second conductive type dopants. For example, the nanosheet 216a has n-type dopants, such as phosphorus, arsenic or a combination thereof, and the nanosheet 216b has p-type dopants, such as boron, BF₂ or a combination thereof.

As shown in FIG. 15A, the nanosheet 216a, 216b has a main portion 217a, 217b and an extension portion 219a, 219b at two ends of the main portion 217a, 217b. In some embodiments, the nanosheets 216a and the nanosheets 216b substantially have the same thickness t corresponding to the thickness of the second blanket layers 206. For example, the nanosheets 216a, 216b has a substantially constant thickness t, that is, the main portion 217a, 217b and the extension portion 219a, 219b both have the thickness t. The thickness t is in a range of about 5 nm and about 15 nm, for example. In some embodiments, the extension portion 219a, 219b is disposed between and protected by the spacers 238 while the main portion 217a. 217b is exposed and suspended. In some embodiments, a height of the gaps 255 between the nanosheets 216a and between the nanosheets 216b is substantially the same and corresponds to the thickness t of the second blanket layers 206. The height of the gaps 255 is in a range of about 5 nm and about 15 nm, for example.

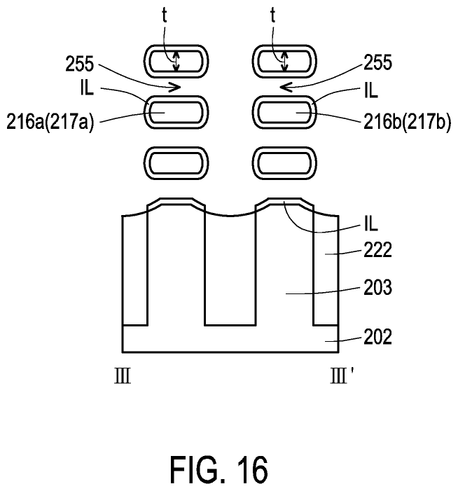

FIG. 16 to FIG. 21 illustrate cross-sectional views of stages of forming a semiconductor device, and FIG. 16 to FIG. 21 are taken along a line III-III′ of FIG. 5. In some embodiments, FIG. 16 to FIG. 21 show the main portions 217a, 217b of the nanosheet 216a, 216b which are exposed and suspended.

Referring to FIG. 16, after forming the nanosheet 216a, 216b, an interlayer IL is formed on surfaces of the nanosheet 216a, 216b. The interlayer IL surrounds the nanosheet 216a, 216b. In some embodiments, the interlayer IL may be deposited or thermally grown respectively on the nanosheets 216a, 216b according to acceptable techniques, and made of, for example, silicon dioxide, a low-k dielectric material (e.g., a material having a dielectric constant lower than silicon dioxide), silicon oxynitride, phosphosilicate glass (PSG), borosilicate glass (BSG), borophosphosilicate glass (BPSG), undoped silicate glass (USG), fluorinated silicate glass (FSG), organosilicate glasses (OSG), SiOxCy, Spin-On-Glass, Spin-On-Polymers, silicon carbon material, a compound thereof, a composite thereof, the like, or a combination thereof. For example, the interlayer IL is a silicon oxide layer formed by an oxidation process such as a wet oxidation process using low temperature sulfuric acid. The thickness of the interfacial layer is in a range from about 0.7 nm to about 2.5 nm in some embodiments. For example, the thickness of the interlayer IL is smaller than 1 nm. In some embodiments, the interlayer IL is immediately formed once the surfaces of the nanosheet 216a, 216b are exposed. In some embodiments, the nanosheet 216a, 216b is Si nanosheet, and the interlayer IL is a silicon oxide layer. In some embodiments, as shown in FIG. 16, the interlayer IL is further formed on exposed surfaces of the fins 203 since the fins 203 are of silicon.

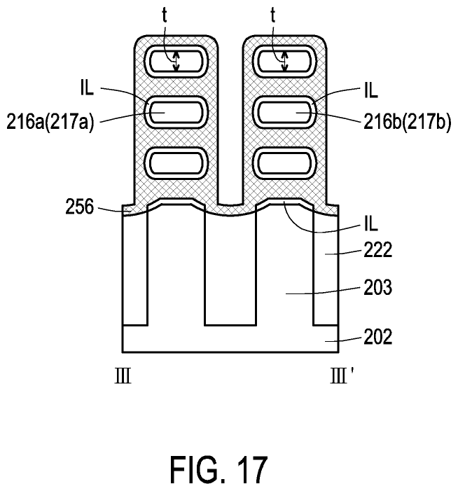

Referring to FIG. 17, a mask layer 256 is formed over the substrate 202 to cover the stack of nanosheets 216a and the stack of nanosheets 216b. In some embodiments, the mask layer 256 covers the stack of nanosheets 216a, the stack of nanosheets 216b, the fins 203 and the insulating regions 222, and the mask layer 256 is formed in the gaps 255 between the nanosheets 216a, 216b. The mask layer 256 may be a hard mask layer and include a dielectric material, such as silicon oxide, silicon nitride, SiON, SiC, SiCN, SiCON, the like, or a combination thereof. Other materials such as a low-k material may be applicable. The low-k material has a dielectric constant less than 3.9, less than 3, less than 2.5, or even less. The mask layer 256 may be formed by chemical vapor deposition (CVD), low pressure CVD (LPCVD), plasma enhanced CVD (PECVD), physical vapor deposition (PVD), atomic layer deposition (ALD), or a suitable process. The thickness of the mask layer 256 is in a range from about 2 nm to about 5 nm in some embodiments.

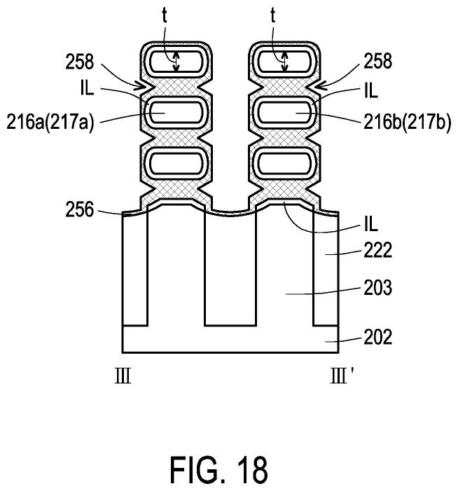

Referring to FIG. 18, an etching process is performed on the mask layer 256, to reduce the thickness of the mask layer 256. This step is optional and used to enlarge the gaps between the stacks of the nanosheets 216b and between the stacks of the nanosheets 216a, to provide enough space for the bit line to be formed. In some embodiments, the etching process is an etchback process. The etching process partially removes the mask layer 256 on the nanosheets 216a, 216b, the fins 203 and the insulating regions 222 without exposing the nanosheets 216a. 216b (e.g., the interlayers IL on the nanosheets 216a. 216b). As shown in FIG. 18, a plurality of recesses 258 are formed between sidewalls of the adjacent nanosheets 216a and between sidewalls of the adjacent nanosheets 216b. After removal, the thickness of the mask layer 256 is in a range from about 0.5 nm to about 5 nm in some embodiments.

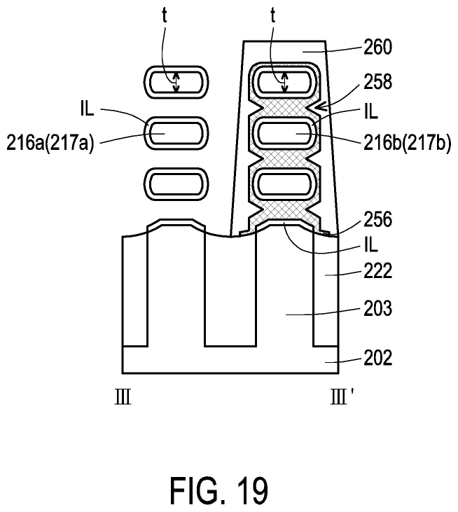

Referring to FIG. 19, a mask layer 260 is formed over the substrate 202 to cover the mask layer 256 over the stack of nanosheets 216b. In some embodiments, the mask layer 260 is formed by blanket depositing a mask material over the substrate 202 and removing the mask material over the nanosheets 216a, so that the mask layer 256 over the nanosheets 216a are exposed while the mask layer 256 over the nanosheets 216b are covered. The mask layer 260 may be a hard mask layer and include a dielectric material, such as silicon oxide, silicon nitride, SiON, SiC, SiCN, SiCON, the like, or a combination thereof. Other materials such as a low-k material may be applicable. The low-k material has a dielectric constant less than 3.9, less than 3, less than 2.5, or even less. The mask layer may be formed by chemical vapor deposition (CVD), low pressure CVD (LPCVD), plasma enhanced CVD (PECVD), physical vapor deposition (PVD), atomic layer deposition (ALD), or a suitable process. The material of the mask layer 260 is different from the material of the mask layer 256, for example.

Then, by using the mask layer 260 as a mask, the mask layer 256 over the nanosheets 216a is removed, so as to expose the interlayers IL on the nanosheets 216a. In some embodiments, the mask layer 256 is removed by using a wet etchant including, for example but not limited to, ammonium hydroxide (NH₄OH) or other suitable etchant. The interlayers IL on the nanosheets 216a are then removed, and thus the nanosheets 216a are exposed. The interlayers IL may be removed by an etching process such as a dry etching or a wet etching. In some embodiments, the interlayer IL disposed on the fin 203 (i.e., fin 203 below the nanosheets 216a) and exposed by the mask layer 260 may be also removed, so as to expose the fin 203.

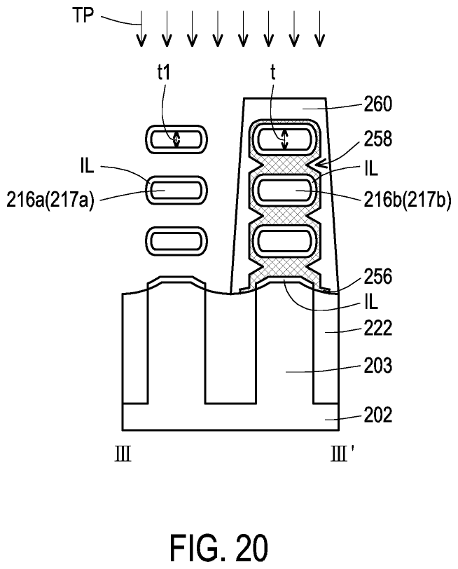

Referring to FIG. 20, a trimming process TP is performed on the nanosheets 216a. The trimming process TP reduces a thickness of the nanosheets 216a to a determined value such as a first thickness t1. For example, the first thickness t1 of the processed nanosheets 216a is in a range of about 4 nm to 6.5 nm. The trimming process TP removes outer portions of the nanosheets 216a. The trimming process TP may be an etching process such as an isotropic etching process. During the trimming process TP, the nanosheets 216b are covered by the mask layer 256, 260, and thus the nanosheets 216b are protected from being processed. As shown in FIG. 20, after the trimming process TP is complete, interlayers IL are re-formed on the exposed nanosheets 216a and the exposed fin 203.

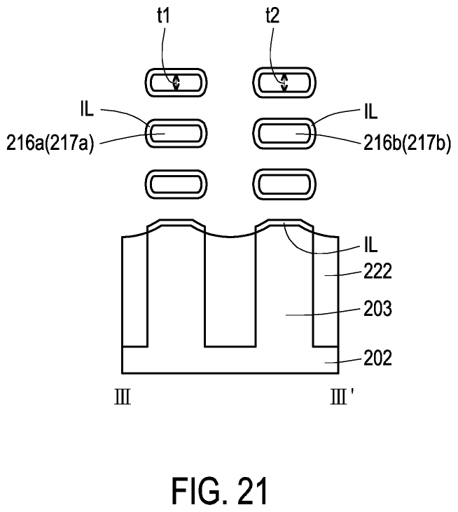

Referring to FIG. 21, the mask layer 260 and the remaining mask layer 256 are removed. In some embodiments, the mask layer 260 is removed by using an ash process or other suitable process, and the remaining mask layer 256 is removed by using a wet etchant including, for example but not limited to, ammonium hydroxide (NH₄OH) or other suitable etchant. In some embodiments, during the removal of the mask layer 260 and the mask layer 256, the nanosheets 216b and the interlayers IL thereon may be inevitably removed. In other words, the interlayers IL are entirely removed and the nanosheets 216b are partially removed, for example. Thus, the thickness t of the nanosheets 216b may be reduced to a second thickness t2. The second thickness t2 of the nanosheets 216b is smaller than thickness t and larger than the first thickness t1 of the processed nanosheets 216a, for example. The second thickness t2 of the nanosheets 216b may be in a range of about 4 nm to 6.5 nm. Then, the interlayers IL remained on the nanosheets 216a, 216b are removed, and interlayers IL are re-formed on the nanosheets 216a, 216b, for example. After that, channel members (or called channel regions) are defined.

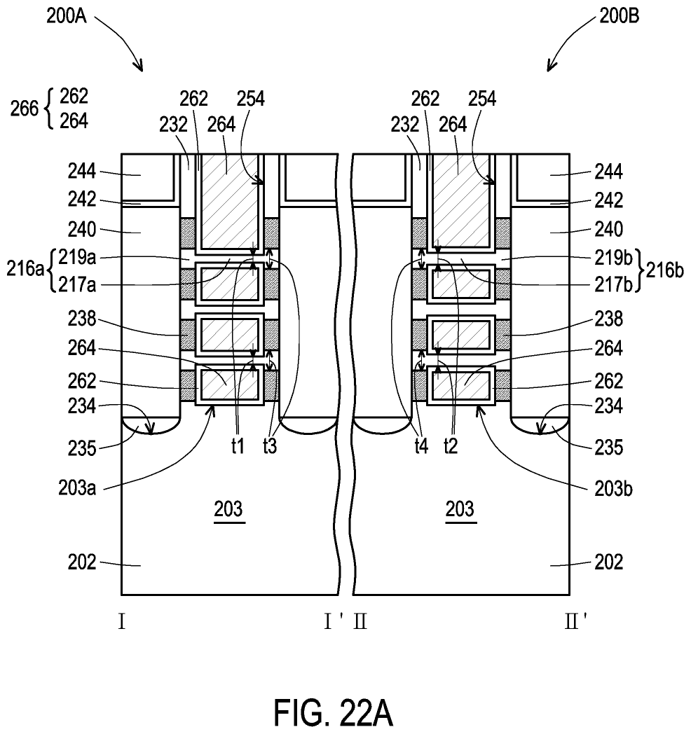

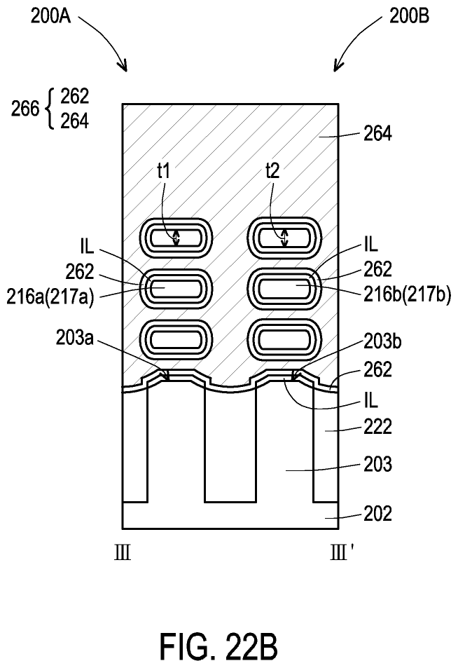

FIG. 22A and FIG. 22B illustrate cross-sectional views of a stage of forming a semiconductor device, FIG. 22A is taken along lines I-I′ and II-II′ of FIG. 5, and FIG. 22B is taken along a line III-III′ of FIG. 5. In FIG. 22A, for clarity, the interlayers IL on the nanosheets 216a, 216b are omitted.

Referring to FIG. 22A and FIG. 22B, a gate dielectric layer 262 is formed in the gate trench 254 and the gaps 255. In some embodiments, the gate dielectric layer 262 conformally covers the gate trench 254 to form a U-shape cross-section, and further conformally covers the surface of each gap 255 exposed to the gate trench 254 to form a circle-like shape cross-section. In some embodiments, the gate dielectric layer 262 includes at least one dielectric material, such as a high-k material. Examples of the high-k material include metal oxide, such as HfO₂, HfSiO, HfSiON, HfTaO, HfTiO, HfZrO, zirconium oxide, aluminum oxide, titanium oxide, hafnium dioxide-alumina (HfO₂—Al₂O₃) alloy, the like, or combinations thereof. The high-k material has a dielectric constant less than 8, less than 15, less than 20, or even more. The gate dielectric layer 262 may be formed by CVD, ALD or a suitable method. In one embodiment, the gate dielectric layer 262 is formed by using a highly conformal deposition process, such as ALD in order to ensure the formation of a gate dielectric layer having a uniform thickness around each channel members. The thickness of the gate dielectric layer 262 is in a range from about 0.5 nm to about 3 nm in some embodiments.

Thereafter, a gate electrode 264 is formed on the gate dielectric layer 262 to surround each of the nanosheets 216a, 216b. In some embodiments, the gate electrode 264 completely fills the gate trench 254 and the gaps 255. In some embodiments, the gate electrode 264 may include one or more conductive materials, such as polysilicon, aluminum, copper, titanium, tantalum, tungsten, cobalt, molybdenum, tantalum nitride, nickel silicide, cobalt silicide, TiN, WN, TiAl, TiAlN, TaCN, TaC, TaSiN, metal alloy, a suitable material, or a combination thereof. The gate electrode 264 may be formed by CVD. ALD, electro-plating, or other suitable method. The gate dielectric layer 262 and the gate electrode 264 may also be deposited over the upper surfaces of the ILD layer 244 and the CESL 242. The gate dielectric layer 262 and the gate electrode 264 formed over the ILD layer 244 and the CESL 242 are then planarized by using, for example, CMP, until the top surfaces of the ILD layer 244 and the CESL 242 are revealed. In some embodiments, after the planarization operation, the gate electrode 264 is recessed and a cap insulating layer (not shown) is formed over the recessed gate electrode 264. The cap insulating layer includes one or more layers of a silicon nitride-based material, such as SiN. The cap insulating layer may be formed by depositing an insulating material followed by a planarization operation.

In other embodiments, one or more work function adjustment layers (not shown) are interposed between the gate dielectric layer 262 and the gate electrode 264. The work function adjustment layers are made of a conductive material, such as a single layer of TiN, TaN, TaAlC, TiC, TaC, Co, Al, TiAl, HfTi, TiSi, TaSi or TiAlC, or a multilayer of two or more of these materials. For the n-type device, one or more of TaN, TaAlC, TiN, TiC, Co, TiAl, HfTi, TiSi and TaSi is used as the work function adjustment layer, and for the p-type device, one or more of TiAlC, Al, TiAl, TaN, TaAlC, TiN, TiC and Co is used as the work function adjustment layer. The work function adjustment layer may be formed by ALD. PVD, CVD, e-beam evaporation, or other suitable process. Further, the work function adjustment layer may be formed separately for the n-type device and the p-type device which may use different metal layers.

In some embodiments, the gate electrode 264 and the gate dielectric layer 262 constitute a gate structure 266. The gate structure 266 wraps the nanosheets 216a may be also referred to a first gate structure, and the gate structure 266 wraps the nanosheets 216b may be also referred to a second gate structure. In some embodiments, as shown in FIG. 22B, the gate structure 266 wrapping the nanosheets 216a and the gate structure 266 wrapping the nanosheets 216b are integrally formed. However, the disclosure is not limited thereto. In some embodiments, the gate structure 266 wrapping the nanosheets 216a and the gate structure 266 wrapping the nanosheets 216b are separately formed and physically separated by a cut gate structure at a suitable location. Upon the formation of the gate structure 266, a semiconductor device 200 of the embodiment is thus accomplished. In some embodiment, the liner layer 235 is configured to line the bottom surfaces and the sidewalls of the strained layers 240. The liner layer 235 is beneficial for epitaxially growing the strained layers 240.

In some embodiments, the semiconductor device 200 includes a first conductive type device 200A and a second conductive type device 200B. For example, the first conductive type transistor 200A is n-type field effect transistor (pFET), the second conductive type transistor 200B is p-type field effect transistor (nFET), and the semiconductor device 200 is a complementary field effect transistor (CFET). However, the disclosure is not limited thereto. The first conductive type transistor 200A may be p-type field effect transistor (pFET), and the second conductive type transistor 200B may be p-type field effect transistor (nFET).

In some embodiments, the nanosheet 216a, 216b has the main portion 217a, 217b between the gate structure 266 and the extension portion 217a, 217b between the spacers 238. Herein, the nanosheet 216a, 216b may be any nanosheet in the stack. For example, the nanosheet 216a, 216b is the topmost nanosheet, and the extension portion 217a, 217b of the topmost nanosheet 216a. 216b is disposed between the spacer 232 (e.g., low-k spacer) and the spacer 238, or the nanosheet 216a, 216b is any nanosheet under the topmost nanosheet. The main portion 217a of nanosheet 216a has the first thickness t1, and the main portion 217b of nanosheet 216b has the second thickness t2. The thickness t1, t2 may be in a range of about 4 nm to about 6.5 nm. The second thickness t2 is larger than the first thickness t1, and a thickness difference ΔT (i.e., ΔT=t2−t1) is larger than 0.5 nm (i.e., ΔT>0.5 nm). In some embodiments, the extension portion 219a is protected by the spacer 232, 238 and has a third thickness t3 larger than the first thickness t1, and the extension portion 219b is protected by the spacer 232, 238 and has a fourth thickness t4 larger than the second thickness t2. The thickness t3, t4 may be in a range of about 5 nm to about 10 nm. Furthermore, the third thickness t3 and the first thickness t1 has a first thickness difference ΔT1 (i.e., ΔT1=t3−t1), the fourth thickness t4 and the second thickness t2 has a second thickness difference ΔT2 (i.e., ΔT2=t4−t2), and a difference Δ′ (i.e., ΔT′=ΔT1−ΔT2) between the first thickness difference ΔT1 and the second thickness difference ΔT2 is larger than 0.5 nm (i.e., ΔT′>0.5 nm). In some embodiments, by processing the nanosheets for one conductive type device, the nanosheets for different type devices may have different thickness. Accordingly, the performance of the complementary field effect transistor may be optimized.

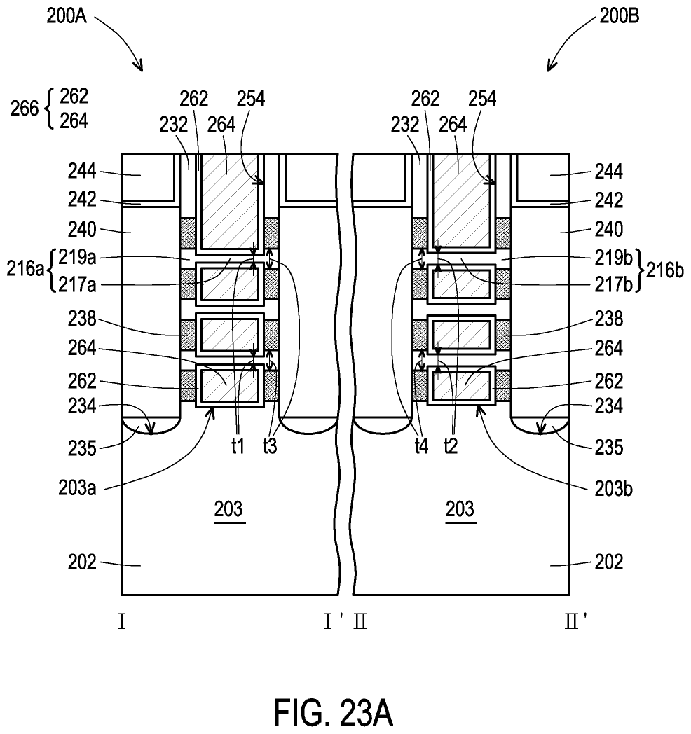

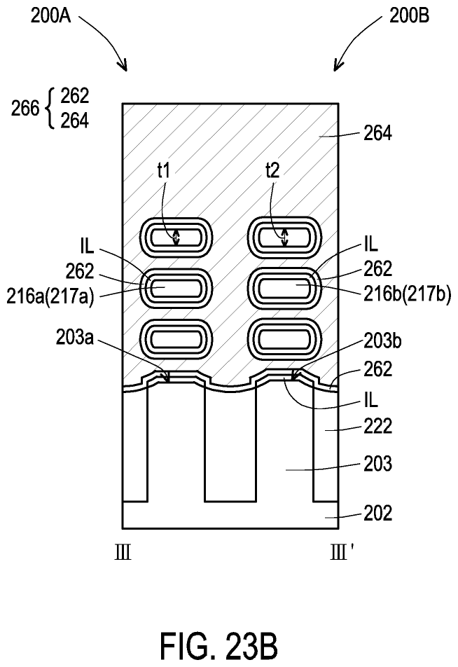

In some embodiments, the partial removal of the fins 203 due to the trimming process TP and/or the removal of the mask layer 260 may be neglected, and thus as shown in FIGS. 22A and 22B, the top surface 203a of the fin 203 below the nanosheets 216a and the top surface 203b of the fin 203 below the nanosheets 216b are shown as being at the substantially same height. However, the disclosure is not limited thereto. In some embodiments in which the fin 203 has the same or similar material as the nanosheets 216a, the fin 203 below the nanosheets 216a may be also partially removed by the trimming process TP. Furthermore, the fin 203 below the nanosheets 216b and the interlayer IL thereon may be also inevitably removed during the removal of the mask layer 260 and the mask layer 256. In such embodiments, as shown in FIGS. 23A and 23B, top surfaces 203a, 203b of the fins 203 below the nanosheets 216a and 216b may be lowered than the top surfaces 203a, 203b of the fins 203 below the nanosheets 216a and 216b as shown in FIG. 15A. The top surface 203a of the fin 203 below the nanosheets 216a top surface of the fin 203 below the nanosheets 216a may be lower than a top surface 203b of the fin 203 below the nanosheets 216b since the removal amount of the fin 203 below the nanosheets 216a by the trimming process TP is larger than the removal amount of the fin 203 below the nanosheets 216b during the removal of the mask layer 256.

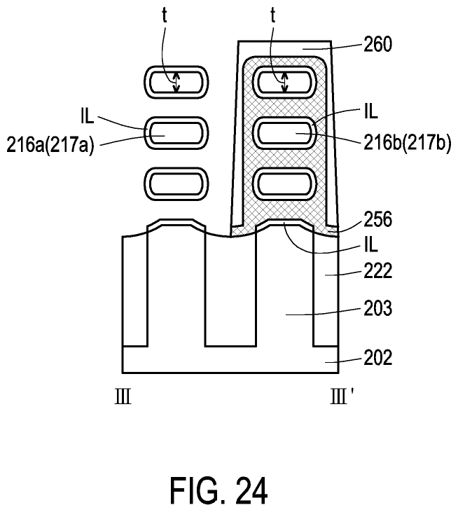

FIG. 24 to FIG. 27 illustrate cross-sectional views of stages of forming a semiconductor device, and FIG. 16 to FIG. 211 are taken along a line III-III′ of FIG. 5. In some embodiments, FIG. 16 to FIG. 21 show the main portions 217a. 217b of the nanosheet 216a, 216b which are exposed and suspended.

Referring to FIG. 24, in some embodiments, after forming the mask layer 256, a mask layer 260 is formed over the substrate 202 to cover the mask layer 256 over the stack of nanosheets 216b. This step is similar to that of FIG. 19, and the main difference between the structure of FIG. 23 and the structure of FIG. 19 lies in that the mask layer 260 covers the nanosheets 216a, 216b without the recesses 258 since the step of FIG. 18 is omitted. In such embodiments, the corners of the nanosheets 216b may be prevented from being removed, which improve the yield of the device 200.

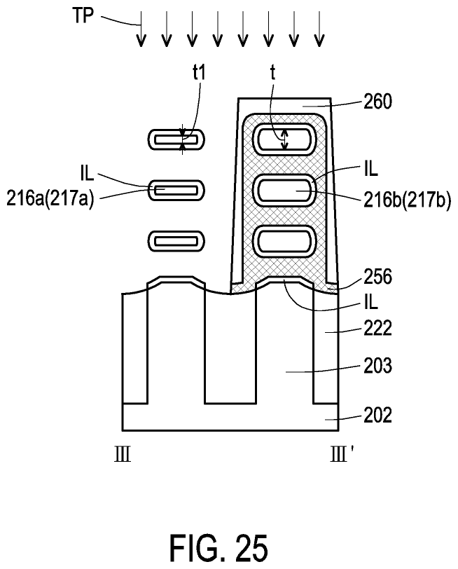

Referring to FIG. 25, a trimming process TP is performed on the nanosheets 216a. The trimming process TP reduces a thickness of the nanosheets 216a to a determined value such as a thickness t1′. For example, the thickness t1′ of the processed nanosheets 216a is in a range of about 2 nm to 4.5 nm. The trimming process TP removes outer portions of the nanosheets 216a. The trimming process TP may be an etching process such as an isotropic etching process. During the trimming process TP, the nanosheets 216b are covered by the mask layer 256, 260, and thus the nanosheets 216b are protected from being processed. In some embodiments in which the fin 203 is exposed, the fin 203 (i.e., fin 203 below the nanosheets 216a) may be also partially removed by the trimming process TP. In such embodiments, a top surface of the fin 203 below the nanosheets 216a may be lower than a top surface of the fin 203 below the nanosheets 216b. As shown in FIG. 25, after the trimming process TP is complete, interlayers IL are re-formed on the exposed nanosheets 216a and the exposed fin 203.

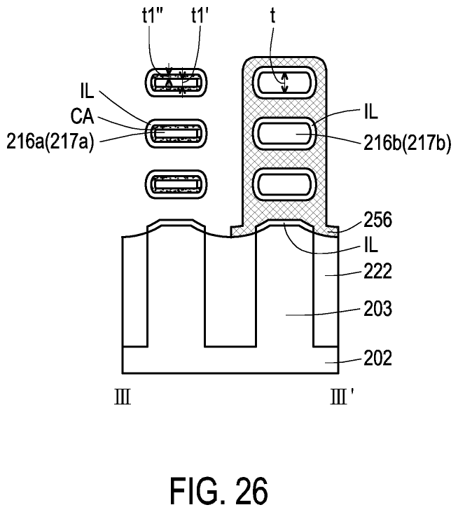

Referring to FIG. 26, the mask layer 260 is removed. In some embodiments, the mask layer 260 is removed by using an ash process or other suitable process. After removing the mask layer 260, the interlayers IL on the nanosheets 216a are removed.

Then, cap layers CA are selectively formed on the nanosheets 216a. The cap layers CA may be selectively formed on the nanosheets 216a (e.g., silicon of nanosheets 216a) by a selective silicon growth (e.g., selective silicon epitaxial growth) which grows a silicon layer on the exposed silicon. The cap layer CA surrounds the nanosheet 216a. In some embodiments, a thickness t1″ of the cap layer CA is in a range of 0.2 nm to 1 nm. An interface may exist or not exist between the cap layer CA and the nanosheet 216a. In an embodiment in which the nanosheet 216a has silicon without dopants, the material of the nanosheet 216a is substantially the same as the cap layer CA, and thus the interface may not exist between the cap layer CA and the nanosheet 216a. On contrary, in an embodiment in which the nanosheet 216a may have dopants due to the diffusion as mentioned before, the interface may exist between the cap layer CA and the nanosheet 216a. As shown in FIG. 26, after the cap layer CA is formed, interlayers IL are re-formed on the exposed cap layers CA on the nanosheets 216a.

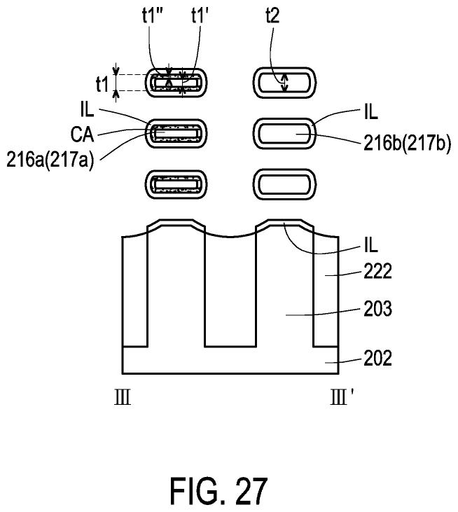

Referring to FIG. 27, the mask layer 256 is removed. In some embodiments, the remaining mask layer 256 is removed by using a wet etchant including, for example but not limited to, ammonium hydroxide (NH₄OH) or other suitable etchant. In some embodiments, during the removal of the mask layer 256, the nanosheets 216b and the interlayers IL thereon may be inevitably removed. In other words, the interlayers IL are entirely removed and the nanosheets 216b are partially removed, for example. Thus, the thickness t of the nanosheets 216b may be reduced to a second thickness t2. The second thickness t2 of the nanosheets 216b is smaller than the thickness t and larger than a total thickness t1 of the processed nanosheets 216a and the cap layer CA, for example. The second thickness t2 of the nanosheets 216b may be in a range of about 4 nm to 6.5 nm. Then, the interlayers IL remained on the nanosheets 216a, 216b are removed, and interlayers IL are re-formed on the nanosheets 216a, 216b, for example. After that, channel members (or called channel regions) are defined.

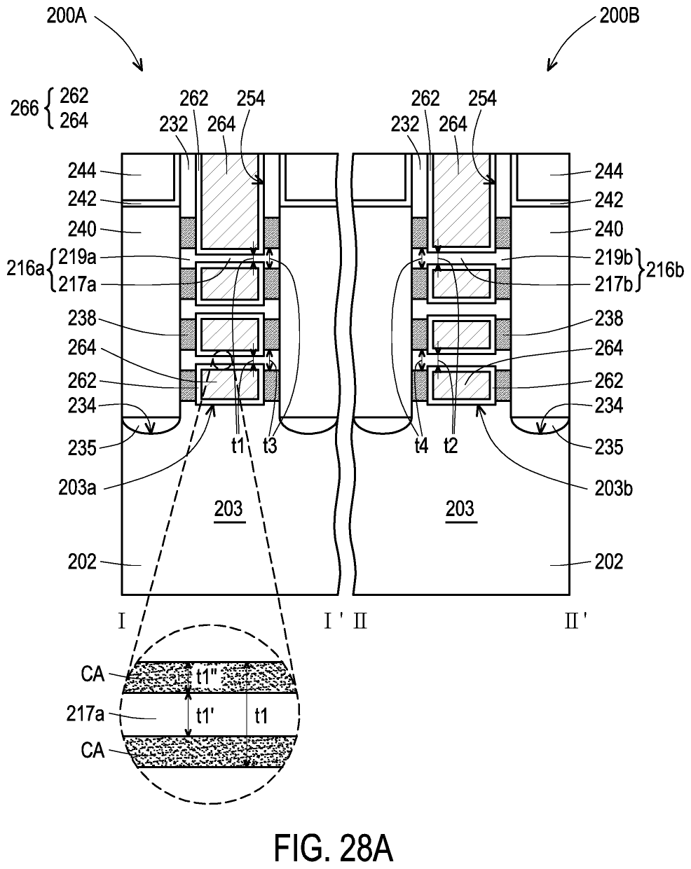

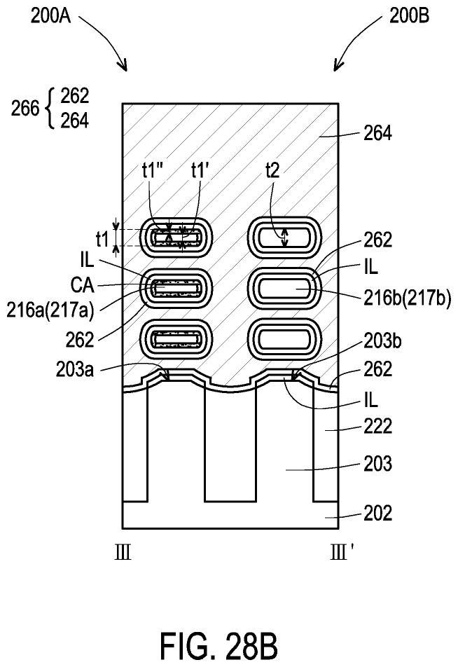

FIG. 28A and FIG. 28B illustrate cross-sectional views of a stage of forming a semiconductor device, FIG. 28A is taken along lines I-I′ and II-II′ of FIG. 5, and FIG. 28B is taken along a line III-III′ of FIG. 5. In FIG. 28A, for clarity, the interlayers IL on the nanosheets 216a, 216b are omitted.

Referring to FIG. 28A and FIG. 28B, a gate dielectric layer 262 is formed in the gate trench 254 and the gaps 255, and a gate electrode 264 is formed on the gate dielectric layer 262 to surround each of the nanosheets 216a, 216b. The formation of the gate dielectric layer 262 and the gate electrode 264 is similar to those described for FIG. 22A and FIG. 22B, and thus is omitted. In some embodiments, as shown in FIG. 28B, the cap layer CA is disposed between the nanosheet 216a and the interlayer IL, and the interlayer IL is disposed between the cap layer CA and the gate dielectric layer 262. After that, a semiconductor device 200 is formed. In some embodiments, the semiconductor device 200 includes a first conductive type device 200A and a second conductive type device 200B. For example, the first conductive type transistor 200A is n-type field effect transistor (pFET), the second conductive type transistor 200B is p-type field effect transistor (nFET), and the semiconductor device 200 is a complementary field effect transistor (CFET). However, the disclosure is not limited thereto. The first conductive type transistor 200A may be p-type field effect transistor (pFET), and the second conductive type transistor 200B may be p-type field effect transistor (nFET).

In some embodiments, the nanosheet 216a, 216b has the main portion 217a, 217b between the gate structure 266 and the extension portion 217a, 217b between the spacers 238. Herein, the nanosheet 216a, 216b may be any nanosheet in the stack. For example, the nanosheet 216a. 216b is the topmost nanosheet, and the extension portion 217a, 217b of the topmost nanosheet 216a, 216b is disposed between the spacer 232 (e.g., low-k spacer) and the spacer 238, or the nanosheet 216a, 216b is any nanosheet under the topmost nanosheet. The main portion 217a of nanosheet 216a has the first thickness t1, and the main portion 217b of nanosheet 216b has the second thickness t2. The thickness t1, t2 may be in a range of about 4 nm to about 6.5 nm. In some embodiments in which the nanosheet 216a has the cap layer CA thereon, the first thickness t1 (i.e., t1=t1′+2t1″) is the total thickness of the thickness t1′ of the nanosheet 216a and two times the thickness t1″ of the cap layer CA. The second thickness t2 is larger than the first thickness t1, and a thickness difference ΔT (i.e., ΔT=t2−t1) is larger than 0.5 nm (i.e., ΔT>0.5 nm). In some embodiments, the extension portion 219a is protected by the spacer 232, 238 and has a third thickness t3 larger than the first thickness t1, and the extension portion 219b is protected by the spacer 232, 238 and has a fourth thickness t4 larger than the second thickness t2. The thickness t3, t4 may be in a range of about 5 nm to about 10 nm. Furthermore, the third thickness t3 and the thickness t1 has a first thickness difference ΔT1 (i.e., ΔT1=t3−t1), the fourth thickness t4 and the second thickness t2 has a second thickness difference ΔT2 (i.e., ΔT2=t4−t2), and a difference ΔT′ (i.e., Δ′=ΔT1−ΔT2) between the first thickness difference ΔT1 and the second thickness difference ΔT2 is larger than 0.5 nm (i.e., ΔT′>0.5 nm). In some embodiments, by processing the nanosheets for one conductive type device and forming the cap layers thereon, the nanosheets for different type devices may have different thickness. Accordingly, the performance of the complementary field effect transistor may be optimized.

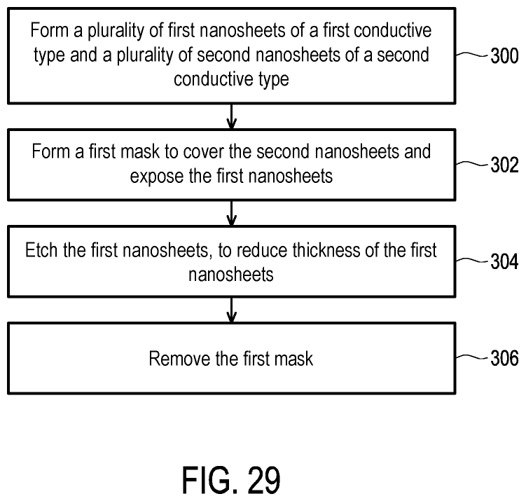

FIG. 29 illustrates a flow chart of a method of forming a semiconductor structure in accordance with some embodiments. Although the method is illustrated and/or described as a series of acts or events, it will be appreciated that the method is not limited to the illustrated ordering or acts. Thus, in some embodiments, the acts may be carried out in different orders than illustrated, and/or may be carried out concurrently. Further, in some embodiments, the illustrated acts or events may be subdivided into multiple acts or events, which may be carried out at separate times or concurrently with other acts or sub-acts. In some embodiments, some illustrated acts or events may be omitted, and other un-illustrated acts or events may be included.

At act 300, a plurality of first nanosheets of a first conductive type and a plurality of second nanosheets of a second conductive type are formed. FIG. 15A and FIG. 15B illustrate cross-sectional views corresponding to some embodiments of act 300.

At act 302, a first mask is formed to cover the second nanosheets and expose the first nanosheets. FIG. 19 and FIG. 24 illustrate cross-sectional views corresponding to some embodiments of act 302.

At act 304, the first nanosheets are etched, to reduce thickness of the first nanosheets. FIG. 20 and FIG. 25 illustrate cross-sectional views corresponding to some embodiments of act 304.

At act 306, the first mask is removed. FIG. 21 and FIG. 27 illustrate cross-sectional views corresponding to some embodiments of act 306.

According to some embodiments, a semiconductor device includes a plurality of first nanosheets of a first conductive type, a plurality of second nanosheets of a second conductive type and a gate structure. The gate structure wraps the first nanosheets and the second nanosheets, wherein a first thickness of at least one of the first nanosheets is smaller than a second thickness of at least one of the second nanosheets.

According to some embodiments, a semiconductor device includes a plurality of first nanosheets of a first conductive type, a plurality of second nanosheets of a second conductive type and a gate structure. At least one of the first nanosheets includes a first main portion and a first extension portion. At least one of the second nanosheets includes a second main portion and a second extension portion. The gate structure wraps the first nanosheets and the second nanosheets. The first main portion has a first thickness, the second main portion has a second thickness, the first extension portion has a third thickness larger than the first thickness, and the second extension portion has a fourth thickness larger than the second thickness, wherein a first difference between the third thickness and the first thickness is larger than a second difference between the fourth thickness and the second thickness.

According to some embodiments, a method of forming a semiconductor device includes the following steps. A plurality of first nanosheets of a first conductive type and a plurality of second nanosheets of a second conductive type are formed. A first mask is formed to cover the second nanosheets and expose the first nanosheets. The first nanosheets are etched, to reduce thickness of the first nanosheets. The first mask is removed.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor device, comprising:
a plurality of first nanosheets of a first conductive type;
a plurality of second nanosheets of a second conductive type; and
a gate structure wrapping the first nanosheets and the second nanosheets, wherein a first thickness of at least one of the first nanosheets is smaller than a second thickness of at least one of the second nanosheets.

2. The semiconductor device of claim 1, wherein the first thickness of each of the first nanosheets is smaller than the second thickness of each of the second nanosheets.

3. The semiconductor device of claim 1, wherein a thickness difference between the first thickness and the second thickness is larger than 0.5 nm.

4. The semiconductor device of claim 1, wherein the at least one of the first nanosheets is the topmost first nanosheet, and the at least one of the second nanosheets is the topmost second nanosheet.

5. The semiconductor device of claim 1, wherein the at least one of the first nanosheets is under the topmost first nanosheet, and the at least one of the second nanosheets is under the topmost second nanosheet.

6. The semiconductor device of claim 1, wherein the at least one of the first nanosheets comprises a first main portion having the first thickness and a first extension portion aside the first main portion and having a third thickness larger than the first thickness, and the at least one of the second nanosheets comprises a second main portion having the second thickness and a second extension portion aside the second main portion and having a fourth thickness larger than the second thickness.

7. The semiconductor device of claim 1, further comprising a cap layer and an interlayer respectively surrounding the at least one of the first nanosheets, wherein the cap layer is disposed between the at least one of the first nanosheets and the interlayer, and the interlayer is disposed between the cap layer and the gate structure.

8. A semiconductor device, comprising:
a plurality of first nanosheets of a first conductive type, at least one of the first nanosheets comprising a first main portion and a first extension portion;
a plurality of second nanosheets of a second conductive type, at least one of the second nanosheets comprising a second main portion and a second extension portion; and
a gate structure wrapping the first nanosheets and the second nanosheets, wherein the first main portion has a first thickness, the second main portion has a second thickness, the first extension portion has a third thickness larger than the first thickness, and the second extension portion has a fourth thickness larger than the second thickness, wherein a first difference between the third thickness and the first thickness is larger than a second difference between the fourth thickness and the second thickness.

9. The semiconductor device of claim 8, wherein the first difference is larger than the second difference 0.5 nm or more.

10. The semiconductor device of claim 8, wherein the at least one of the first nanosheets is the topmost first nanosheet, and the at least one of the second nanosheets is the topmost second nanosheet.

11. The semiconductor device of claim 8, wherein the at least one of the first nanosheets is under the topmost first nanosheet, and the at least one of the second nanosheets is under the topmost second nanosheet.

12. The semiconductor device of claim 8, wherein the gate structure is in direct contact with the first main portion of the at least one of the first nanosheets and the second main portion of the at least one of the second nanosheets.

13. The semiconductor device of claim 8, further comprising:
first spacers on a sidewall of the gate structure wrapping the first nanosheets, wherein the first extension portion of the at least one of the first nanosheets is disposed between the first spacers; and
second spacers on a sidewall of the gate structure wrapping the second nanosheets, wherein the second extension portion of the at least one of the second nanosheets is disposed between the second spacers.

14. The semiconductor device of claim 8, further comprising a cap layer and an interlayer respectively surrounding the at least one of the first nanosheets, wherein the cap layer is disposed between the at least one of the first nanosheets and the interlayer, and the interlayer is disposed between the cap layer and the gate structure.

15. A method of forming a semiconductor device, comprising:
forming a plurality of first nanosheets of a first conductive type and a plurality of second nanosheets of a second conductive type;
forming a first mask to cover the second nanosheets and expose the first nanosheets;
etching the first nanosheets, to reduce thickness of the first nanosheets; and
removing the first mask.

16. The method of claim 15, further comprising:
forming a second mask to cover the first nanosheets and the second nanosheets;
forming the first mask over the second mask to cover the second mask over the second nanosheets and expose the second mask over the first nanosheets;
removing the second mask over the first nanosheets, to expose the first nanosheets;
etching the first nanosheets while the second nanosheets are covered by the first mask and the second mask; and
removing the second mask over the second nanosheets.

17. The method of claim 16, before forming the first mask, further comprising removing portions of the second mask, to reduce a thickness of the second mask.

18. The method of claim 16, after removing the first mask, further comprising:
forming cap layers to surround the first nanosheets respectively while the second nanosheets are covered by the second mask; and
removing the second mask.

19. The method of claim 18, wherein the cap layers are formed by using a selective silicon growth.

20. The method of claim 15, further comprising:
forming a gate structure, to wrap the first nanosheets and the second nanosheets.
